(19) United States
(12) Patent Application Publication
(10) Pub. No.: US 2011/0024650 A1
(43) Pub. Date: Feb. 3, 2011

(54) TERAHERTZ EMITTER WITH HIGH POWER AND TEMPERATURE OPERATION

(75) Inventors: JAMES KOLODZEY, Landenberg, PA (US); Matthew Coppinger, Newark, DE (US); Guangchi Xuan, Santa Clara, CA (US); Pengcheng Lv, Newark, DE (US)

Correspondence Address: RATNERPRESTIA, P.O. BOX 1596, WILMINGTON, DE, 19899, US

(73) Assignee: UNIVERSITY OF DELAWARE, Newark, DE (US)

(21) Appl. No.: 12/796,795

(22) Filed: Jun. 9, 2010

Related U.S. Application Data
(60) Provisional application No. 61/185,436, filed on Jun. 9, 2009.

(51) Int. Cl. G21K 5/02; H01L 29/66

(52) U.S. Cl. 250/493.1; 257/77; 257/E29.166

(57) ABSTRACT

Terahertz emitting devices are disclosed. The terahertz emitting device comprises a wafer and a current source. The wafer includes silicon carbide and a dopant. In particular, the wafer may consist of 6H silicon carbide; a nitrogen dopant having a concentration of approximately 10¹⁸ cm⁻³; a boron dopant having a concentration of approximately 10¹⁶ cm⁻³; and an aluminum dopant having a concentration of approximately 10¹⁵ cm⁻³. The current source is electrically coupled to the wafer. The wafer emits radiation having a frequency between approximately 1 THz and 20 THz when driven by the current source.

### CROSS REFERENCE TO RELATED APPLICATIONS

This application claims the benefit of provisional U.S. Patent Application No. 61/185,436, filed Jun. 9, 2009, which is fully incorporated herein by reference.

### STATEMENT REGARDING FEDERALLY SPONSORED RESEARCH

The National Science Foundation (under grant Award No. DMR-0601920) and the Air Force Office of Scientific Research (under grant F49620-03-1-0380) provided funding related to the research leading to this invention. The government may have rights to this invention.

### FIELD OF THE INVENTION

The present invention relates to electromagnetic radiation sources, and more particularly, to terahertz emitters.

### BACKGROUND OF THE INVENTION

In recent years, terahertz radiation has gained use in imaging, spectroscopy, ranging, and telecommunications applications. Devices that emit terahertz radiation are therefore useful in a number of different fields. Conventional terahertz emitters are typically cooled to very low or cryogenic temperatures in order to operate effectively, which makes such terahertz emitters expensive to operate. Thus, improved terahertz emitters are desirable.

### SUMMARY OF THE INVENTION

The present invention is embodied in devices for emitting terahertz radiation.

In accordance with one aspect of the present invention, a terahertz emitting device is disclosed. The terahertz emitting device comprises a wafer and a current source. The wafer includes silicon carbide and a dopant. The current source is electrically coupled to the wafer. The wafer emits radiation having a frequency between approximately 1 THz and 20 THz when driven by the current source.

In accordance with another aspect of the present invention, a wafer for a terahertz emitting device is disclosed. The wafer comprises 6H silicon carbide and a nitrogen dopant.

In accordance with still another aspect of the present invention, a wafer for a terahertz emitting device is disclosed. The wafer consists of 6H silicon carbide; a nitrogen dopant having a concentration of approximately 10¹⁸ cm⁻³; a boron dopant having a concentration of approximately 10¹⁶ cm⁻³; and an aluminum dopant having a concentration of approximately 10¹⁵ cm⁻³.

### BRIEF DESCRIPTION OF THE DRAWINGS

The invention is best understood from the following detailed description when read in connection with the accompanying drawings, with like elements having the same reference numerals. According to common practice, the various features of the drawings are not drawn to scale unless otherwise indicated. On the contrary, the dimensions of the various features may be expanded or reduced for clarity. Included in the drawings are the following figures:

FIG. 1 is a diagram view of an exemplary terahertz emitting device in accordance with aspects of the present invention;

FIG. 2 is a graph showing the concentration of dopants in an exemplary wafer of the device of FIG. 1;

FIG. 3 is a top view of an exemplary wafer in accordance with aspects of the present invention;

FIG. 4 is an exemplary graph of emission spectra for varying currents for the device of FIG. 1;

FIG. 5 is an exemplary graph of emission spectra for varying temperatures for the device of FIG. 1; and

FIG. 6 is an exemplary graph of emission power for varying temperatures for the device of FIG. 1.

### DETAILED DESCRIPTION OF THE INVENTION

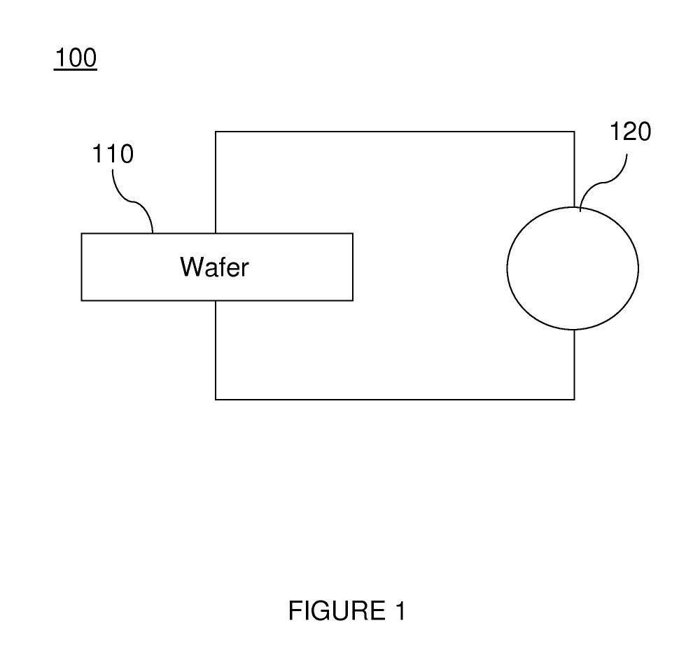

Referring now to the drawings, FIG. 1 illustrates an exemplary terahertz emitting device 100 in accordance with aspects of the present invention. Terahertz emitting device 100 may emit radiation having a frequency between approximately 1 THz and 20 THz. As a general overview, device 100 includes a wafer 110 and a current source 120. Additional details of terahertz emitting device 100 are described below.

Wafer 110 is a semiconductor wafer. As explained herein, it is desirable that wafer 110 operate at relatively high temperatures, e.g., above 50 K. While not intending to be bound to any particular theory, the inventors contemplate that the use of materials having relatively large ionization energies for wafer 110 enable such high temperature operation. Suitable materials include those having a large energy bandgap such as, for example, silicon carbide, gallium nitride, and diamond. In an exemplary embodiment, wafer 110 comprises doped silicon carbide (SiC). The silicon carbide may be semiconducting device-grade silicon carbide such as n-type 6H silicon carbide. Silicon carbide is particularly desirable due to its high thermal conductivity, which enables it to sustain high drive currents without excessive heating.

In an exemplary embodiment, and as further described below, the dopant in wafer 110 has a deeper ionization energy than conventional dopants in semiconductor wafers. The dopant in wafer 110 may be selected such that the dopant has energy levels corresponding to the desired THz emission. For example, the relationship between ionization energies and terahertz emission may be approximately 4.1 meV per THz. Thus, dopants with ionization energy of about 45 meV, such as boron or phosphorus in silicon, produce emission at about 36 meV, which corresponds to emitted radiation of approximately 9 THz. Further, a dopant having deep ionization energy allows the terahertz emitting device 100 to operate at higher temperatures than conventional devices.

In an exemplary embodiment, the silicon carbide wafer is doped with nitrogen. For example, wafer 110 may comprise nitrogen-doped 4H silicon carbide. The nitrogen dopant in 4H—SiC has ionization energies of approximately 52.1 meV for the h-site (hexagonal) and approximately 91.8 meV for the k-site (cubic). In another example, wafer 110 may comprise nitrogen-doped 6H silicon carbide. The nitrogen dopant in 6H—SiC has deeper ionization energies (with respect to 4H—SiC) of approximately 81 meV for the h-site, approximately 137.6 meV for the k1 site, and approximately 142.4 meV for the k2 site. The nitrogen dopant desirably has a concentration of between approximately 10¹⁶ cm⁻³ and 10¹⁸ cm⁻³. It will be understood by one of ordinary skill in the art from the description herein that low concentrations may provide insufficient dopants to produce the emission. Conversely, higher concentrations may cause dopants to be so close together that they can interact, forming an undesirable impurity band. The electrons in the impurity band can conduct away from the dopant, rather than undergoing the THz-producing transitions. In an exemplary embodiment, the nitrogen dopant has a concentration of approximately 10¹⁸ cm⁻³.

Wafer 110 may further comprise at least one additional dopant. In an exemplary embodiment, wafer 110 is doped with boron and aluminum in addition to the nitrogen dopant. The boron dopant desirably has a concentration of approximately 10¹⁶ cm⁻³, and the aluminum dopant desirably has a concentration of approximately 10¹⁵ cm⁻³.

Suitable technologies for producing wafers 110 such as those described herein will be understood by one of ordinary skill in the art from the description herein.

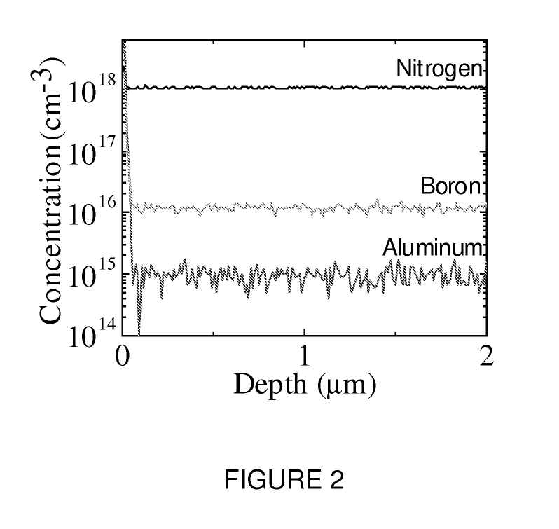

FIG. 2 is a graph showing the concentration of dopants in wafer 110 in accordance with aspects of the present invention. In an exemplary embodiment, wafer 100 consists only of 6H silicon carbide, a nitrogen dopant having a concentration of approximately 10¹⁸ cm⁻³, a boron dopant having a concentration of approximately 10¹⁶ cm⁻³, and an aluminum dopant having a concentration of approximately 10¹⁵ cm⁻³.

Referring back to FIG. 1, current source 120 is electrically coupled to wafer 110, such that current source 120 is able to drive a current through wafer 110. In an exemplary embodiment, current source 120 is a pulse generator. Suitable current sources 120 include, for example, an Avtech AVR-5B-B Pulse Generator. Other suitable current sources 120 will be understood by one of ordinary skill in the art from the description herein.

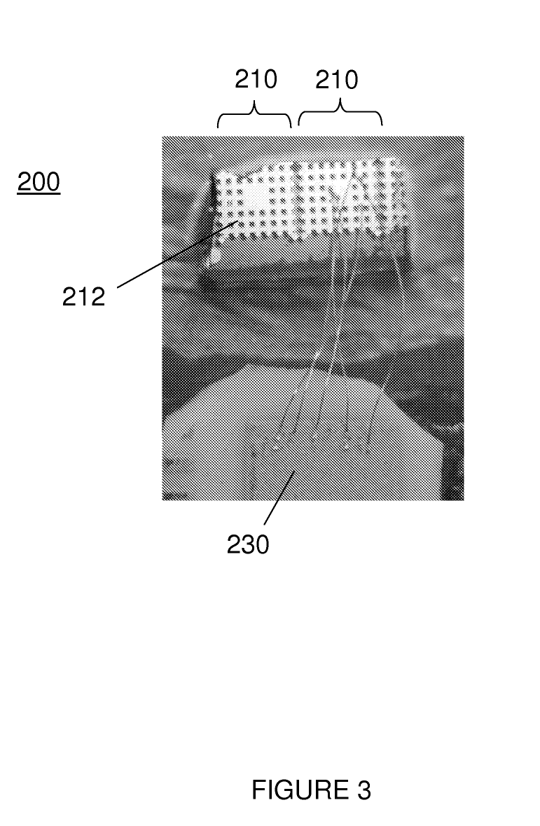

Fabrication of an exemplary terahertz emitting device 200 will now be described. In an exemplary embodiment, a wafer 210 is formed from a 625 μm thick double-sided polished n-type 6H—SiC wafer of 0.1 Ohm-cm resistivity (at room temperature) having nitrogen donors at a concentration of 10¹⁸ cm⁻³. As set forth above, the wafer 210 includes compensating dopants such as 10¹⁶ cm⁻³ of Boron and 10¹⁵ cm⁻³ of Aluminum, as indicated by FIG. 2. The silicon carbide wafer may be doped by conventional means. For fabrication, wafer pieces 210 may be RCA cleaned. Next, the wafer pieces 210 are patterned using contact photolithography to define a mesh-shaped metal contact pattern 212 in photoresist on the front and back surfaces of the wafers. The contact pattern may have 80 μm lines and spaces, for a 50% shading factor. The metal contacts 212 are formed using electron beam evaporation of metallic Ti/Au (10 nm/300 nm). After photoresist lift-off, the wafer pieces 210 may be cut into 1×1 mm² and 1×2 mm² and then mounted onto a copper block heat sink using low temperature conductive epoxy with high electrical and thermal conductivity. Suitable epoxies include, for example, silver-filled epoxy such as that provided by Lakeshore Cryotronics, part number ESF-2. FIG. 3 shows an image of two wafers 210 fabricated on a 1×2 mm² die, with one wafer wire-bonded to a soldering pad 230.

Operation of the above-described terahertz emitting device 100 will now be described. Current source 120 generates a current through wafer 110. In an exemplary embodiment, current source 120 applies a sub-microsecond pulsed current between 500 milliamps and 4 amps to wafer 110. The current may have a pulse length of, for example, between approximately 50 nanoseconds and approximately 1 microsecond. The wafer 110 emits terahertz radiation in response to the current through the mechanism of radiative transition between the hydrogen-like bound states of the dopant(s) in wafer 110. As such, the operating temperature of wafer 110 is limited by the ionization energies of the dopants, as set forth above. The dopant(s) may optionally be selected as described below such that terahertz emitting device 100 operates above room temperature (e.g., between approximately 293 K and 298 K) when a pulsed current is applied from current source 120.

Wafer 110 emits terahertz radiation when driven by current source 120. In an exemplary embodiment, a nitrogen-doped wafer 110 emits radiation having a frequency between 1 THz and 20 THz when driven by current source 120. The spectrum of the terahertz radiation emitted by the nitrogen-doped wafer 110 has peaks centering around approximately 4.7 THz and approximately 12 THz. These peaks may be attributed to radiative transitions of the nitrogen dopant, at approximately 20 meV and approximately 50 meV, respectively.

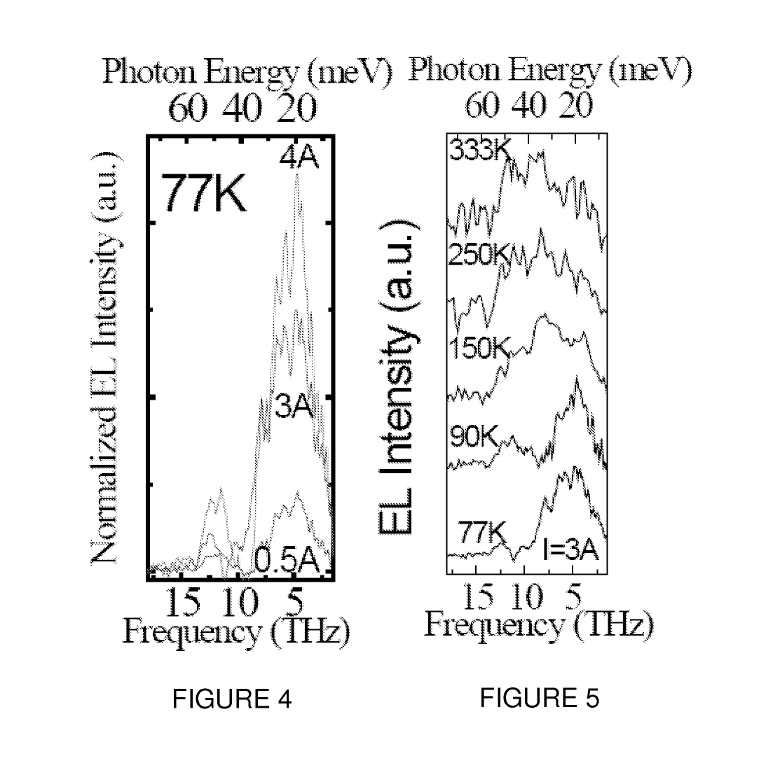

FIGS. 4-6 illustrate features of the above-described exemplary terahertz emitting device 100 consisting of 6H silicon carbide, a nitrogen dopant having a concentration of approximately 10¹⁸ cm⁻³, a boron dopant having a concentration of approximately 10¹⁶ cm⁻³, and an aluminum dopant having a concentration of approximately 10¹⁵ cm⁻³. It will be understood that the illustrated features correspond to this exemplary embodiment, and that different exemplary embodiments of device 100 may have alternative or additional characteristics. FIG. 4 illustrates an exemplary emission spectrum for device 100 for various currents provided by current source 120. As illustrated in FIG. 4, the emission spectra of device 100 increases in intensity as the pulse amplitude of the current from current source 120 goes from 0.5 to 4 Amp at 77 K. Additionally, FIG. 5 illustrates exemplary emission spectra at the same pumping current of 3 Amp over a temperature range from 77 K to 333 K. As the temperature increases from 90 K to 150 K, the two emission peaks around approximately 4.7 THz and approximately 12 THz broaden and merge.

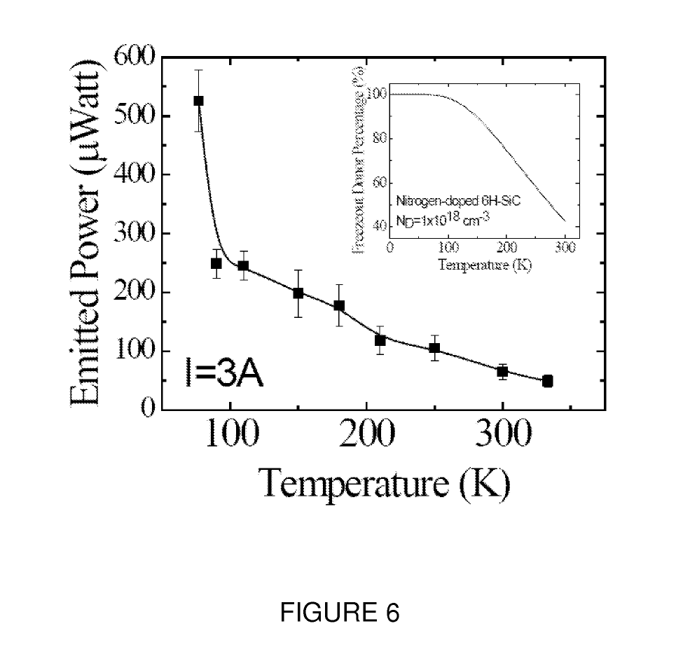

FIG. 6 is an exemplary graph of emitted power versus temperature from 77 K to 333 K at the same 3 Amp peak pumping current. As illustrated in FIG. 6, the radiation emitted by wafer 110 has a power of at least 500 μW at liquid nitrogen temperature, 77 K. The emitted power then experiences two drops as the temperature increases: a steep drop from 526 μW at 77 K to 249 μW at 90 K, and a gradual decrease from 249 μW at 90 K to 49 μW at 333 K. This may imply that two thermal activation energies are involved in generating the radiation being emitted. Nonetheless, as illustrated in FIG. 6, the radiation emitted by wafer 110 has a power of at least 40 μW at temperatures above room temperature, e.g., 333 K. The ability of terahertz emitting device 100 to operate with high output powers and at temperatures well above room temperature enables device 100 to be used for practical applications such as in the fields of medicine, remote sensing, the detection of biochemicals, and high speed communication.

The inset to FIG. 6 illustrates the calculated donor freeze-out percentage for wafer 110. Below temperatures of ˜100 K, most of the nitrogen donors may be frozen in the ground states and thereby be available for impact ionization to excite radiative transitions. Below 100 K, the reduction in emitted power with temperature may be attributable to field-dependent ionization. Due to thermal ionization as the temperature increases, fewer electrons may be frozen in the donor ground states, thereby reducing the output power of the device, as shown in FIG. 6.

The exemplary devices disclosed herein provide advantages over conventional devices, as set forth below. The exemplary devices disclosed herein are capable of serving as sources of emitted power in the far infrared (terahertz) regime, with wavelengths from approximately 15 to 150 micrometers. In contrast, conventional infrared lasers and light emitting diodes that are used for optical fiber communication operate at wavelengths from 1 to 2 micrometers. Thus, the terahertz emitting devices disclosed herein can be used to illuminate materials and objects for numerous practical applications that require long wavelength signals. The terahertz signals can penetrate many materials, just as radio waves penetrate walls, but unlike radio waves, can interact with the unique spectral signatures of biochemicals and thus can be used for material identification. Suitable applications for the disclosed terahertz emitting devices include see-through imaging, medical diagnostics, pharmaceutical monitoring, remote sensing, the detection of biochemicals, and high speed communication.

The exemplary devices disclosed herein may be particular suitable to emit terahertz radiation at significantly higher output power and ambient temperature than conventional devices. Due to the relatively deep binding energies of dopants such as nitrogen, which as described above may exceed 100 meV, and due to the high thermal conductivity of wafers formed from materials such as silicon carbide, the output power and operating temperature may be significantly higher than any previous dopant-based terahertz emitters.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A terahertz emitting device comprising:
a wafer including silicon carbide and a dopant; and
a current source electrically coupled to the wafer, the wafer emitting radiation having a frequency between approximately 1 THz and 20 THz when driven by the current source.

2. The device of claim 1, wherein:
the silicon carbide comprises n-type 6H silicon carbide.

3. The device of claim 2, wherein:
the dopant comprises nitrogen.

4. The device of claim 3, wherein:
the dopant has a concentration of approximately 10¹⁸ cm⁻³.

5. The device of claim 3, wherein the wafer further comprises at least one other dopant.

6. The device of claim 5, wherein the at least one other dopant is selected from the group consisting of boron and aluminum.

7. The device of claim 6, wherein the at least one other dopant has a concentration of from approximately 10¹⁵ cm⁻³ to approximately 10¹⁶ cm⁻³.

8. The device of claim 1, wherein the radiation emitted by the wafer has a power of at least 500 μW when a temperature of the wafer is approximately 77K.

9. The device of claim 1, wherein the radiation emitted by the wafer has a power of at least 40 μW when a temperature of the wafer is approximately 333K.

10. A wafer for a terahertz emitting device, the wafer comprising 6H silicon carbide and a nitrogen dopant.

11. The wafer of claim 10, wherein the nitrogen dopant has a concentration of approximately 10¹⁸ cm⁻³.

12. The wafer of claim 11, wherein the wafer further comprises at least one other dopant.

13. The wafer of claim 12, wherein the at least one other dopant is selected from the group consisting of boron and aluminum.

14. The wafer of claim 13, wherein the at least one other dopant has a concentration of from approximately 10¹⁵ cm⁻³ to approximately 10¹⁶ cm⁻³.

15. A wafer for a terahertz emitting device, the wafer consisting of:
6H silicon carbide;
a nitrogen dopant having a concentration of approximately 10¹⁸ cm⁻³;
a boron dopant having a concentration of approximately 10¹⁶ cm⁻³; and
an aluminum dopant having a concentration of approximately 10¹⁵ cm⁻³.
